(19) United States
(12) Patent Application Publication
(10) Pub. No.: US 2008/0054163 A1
(43) Pub. Date: Mar. 6, 2008

(54) LOGARITHMIC-COMPRESSION ANALOG-DIGITAL CONVERSION CIRCUIT AND SEMICONDUCTOR PHOTOSENSOR DEVICE

(75) Inventor: Hiroshi Suzunaga, Kanagawa-ken (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/844,736

(22) Filed: Aug. 24, 2007

(30) Foreign Application Priority Data
Aug. 25, 2006 (JP) 2006-228677

(51) Int. Cl. H03M 1/12; G01J 1/44

(52) U.S. Cl. 250/214 A; 341/155

(57) ABSTRACT

A logarithmic-compression analog-digital conversion circuit, includes: a logarithmic amplifier; and a converter. The logarithmic amplifier is configured to logarithmically convert an input current to a voltage using forward characteristics of a p-n junction, and configured to output the voltage. The converter is configured to output a digital signal based on the output voltage of the logarithmic amplifier while reducing temperature dependence of the logarithmic amplifier by successively comparing the output voltage with a voltage generated from a reference voltage source which has a temperature dependence.

### CROSS-REFERENCE TO RELATED APPLICATIONS

This application is based upon and claims the benefit of priority from the prior Japanese Patent Application No. 2006-228677, filed on Aug. 25, 2006; the entire contents of which are incorporated herein by reference.

### BACKGROUND OF THE INVENTION

There are many types of photosensor devices based on semiconductor light receiving elements. One example is a luminance sensor. The luminance sensor can output an electrical signal corresponding to the ambient illuminance (brightness), and hence is widely used in portable electronic devices such as mobile phones.

For example, in a dark environment, a backlight for liquid crystal display or an LED (light emitting diode) in the operation keypad is turned on with brightness adjustment. On the other hand, in a light environment, the backlight or LED is turned off. Thus, by extinction and brightness adjustment depending on the ambient illuminance, power consumption can be reduced while maintaining high visibility.

Taking a mobile phone as an example, the keypad LED is typically switched on/off in a low luminance range of several to 100 lux. Conventional illuminance sensors are designed to provide linear output in the illuminance range of several to 100 lux because they are often used for switching on/off the keypad illumination.

However, there is a growing demand for high-speed, large-capacity information transmission in mobile phones, accordingly requiring a full-color liquid crystal display with high-definition display capability. High-definition display using a full-color liquid crystal display needs brightness adjustment for liquid crystal backlight and chromaticity adjustment (gamma correction) in response to the ambient illuminance. Here, brightness adjustment and chromaticity adjustment (gamma correction) are preferably performed in the illuminance range up to several ten thousand lux. Of course, it is also necessary to provide a low illuminance control function for switching on/off the keypad LED.

An illuminance sensor for keypad control, which is highly sensitive in the low illuminance range, cannot detect correct illuminance because its output is saturated for high illuminance of several ten thousand lux. Conversely, in an illuminance sensor with decreased sensitivity for detecting high illuminance of several ten thousand lux, its output at low illuminance to be used for controlling the keypad cannot be distinguished from dark current, making illuminance detection difficult.

A logarithmic amplifier, which uses the forward current-voltage characteristics of a p-n junction to logarithmically compress its output voltage, is suitable for detecting illuminance over a wide dynamic range as described above. However, the logarithmically converted voltage output 0 varies due to the temperature characteristics of the p-n junction. Hence temperature dependence occurs in the digital output, which is obtained by inputting a comparison voltage of a voltage dividing resistor and a logarithmically converted voltage output to a comparator for successive approximation. Consequently, the detected illuminance has an insufficient precision.

### SUMMARY

According to an aspect of the invention, there is provided a logarithmic-compression analog-digital conversion circuit, including: a logarithmic amplifier configured to logarithmically convert an input current to a voltage using forward characteristics of a p-n junction, and configured to output the voltage; and a converter configured to output a digital signal based on the output voltage of the logarithmic amplifier while reducing temperature dependence of the logarithmic amplifier by successively comparing the output voltage with a voltage generated from a reference voltage source which has a temperature dependence.

According to another aspect of the invention, there is provided a logarithmic-compression analog-digital conversion circuit, including: a means for converting an input current to an logarithmically compressed voltage using forward characteristics of a p-n junction, a means for generating a reference voltage which has a temperature dependence, and a means for outputting a digital signal while reducing temperature dependence of the logarithmically compressed voltage by successively comparing the logarithmically compressed voltage with the reference voltage.

According to another aspect of the invention, there is provided a semiconductor photosensor device, including: a photoelectric conversion element; a logarithmic amplifier configured to logarithmically convert an input current to a voltage using forward characteristics of a p-n junction, and configured to output the voltage; and a converter configured to output a digital signal based on the output voltage of the logarithmic amplifier while reducing temperature dependence of the logarithmic amplifier by successively comparing the output voltage with a voltage generated from a reference voltage source which has a temperature dependence.

### BRIEF DESCRIPTION OF THE DRAWINGS

FIG. 1 is a block diagram showing a logarithmic-compression analog-digital conversion circuit according to an example of the invention;

FIGS. 2A and 2B are graphs for a description of the operation of using the temperature-dependent reference voltage sources to cancel the temperature variation of logarithmically converted output voltage;

FIGS. 3A and 3B are graphs of a variation for setting of the reference current value;

FIGS. 4A and 4B are graphs of the other variation for setting of the reference current value;

FIG. 5 is a block diagram of a photosensor device according to an example of the invention; and

FIGS. 6A and 6B are circuits of the temperature-dependent reference voltage sources.

### DETAILED DESCRIPTION OF THE INVENTION

An embodiment of the invention will now be described with reference to the drawings.

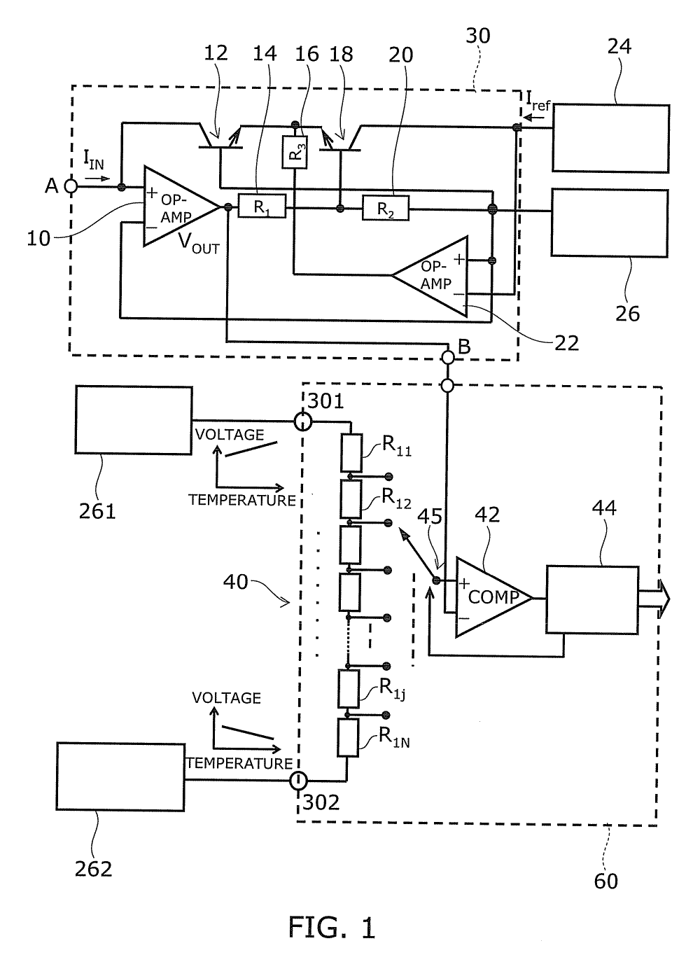

FIG. 1 is a block diagram showing a logarithmic-compression analog-digital conversion circuit according to an example of the invention.

This conversion circuit comprises a logarithmic amplifier 30 and an A/D converter 60. The logarithmic amplifier 30 performs logarithmic compression using nonlinearity of a p-n junction. More specifically, the relationship between voltage V_{D} and current I_{D} at a p-n junction can be expressed by equation (1):

$${V}_{D} = 2.30 \frac{kT}{q} {log}_{10} ( \frac{{I}_{D}}{{I}_{S}} + 1 ) \qquad ( 1 )$$

where I_{S} is the reverse current of the p-n junction, k is the Boltzmann constant, T is the absolute temperature, and q is the electron charge. A current value is converted to a voltage value by using this relationship. The p-n junction can be a diode, or an emitter-base junction of a bipolar transistor.

The logarithmic amplifier 30 illustrated in FIG. 1 uses an emitter-base junction of a transistor. More specifically, an input current I_{IN} is logarithmically converted to an output voltage V_{OUT} by a transistor 12. However, because of the large temperature dependence of I_{S} in equation (1), V_{D} also has a large temperature dependence. That is, the base-emitter junction of a transistor has a large temperature dependence. To cancel this, another transistor 18 is provided. The impact of I_{S} can be reduced by matching the temperature characteristics between the transistor 12 and the transistor 18, and the temperature variation of the output voltage V_{OUT} can be reduced.

In the conversion circuit shown in FIG. 1, the input current I_{IN} flows into the input terminal A of the logarithmic amplifier 30. The input terminal A is connected to the positive input terminal of an operational amplifier 10 and to the collector of the transistor 12. On the other hand, a reference current source 24 is connected to the collector of the transistor 18 and to the negative input terminal of another operational amplifier 22. The negative input terminal of the operational amplifier 10, a reference voltage source 26, and a resistor R₂ are connected to the positive input terminal of the operational amplifier 22.

The output of the operational amplifier 22 is connected through a resistor R₃ to the emitters of the two transistors 12 and 18. The output terminal of the operational amplifier 10 is connected to a resistor R₁ to constitute an output terminal B of the logarithmic amplifier 30. A logarithmically converted output voltage V_{OUT} is extracted from this output terminal B. The resistor R₁ is connected to the resistor R₂ and the base terminal of the transistor 18.

Even this logarithmic amplifier 30 is still insufficient for canceling the temperature variation of the current-voltage conversion coefficient. Here, this temperature variation can be reduced at about 300K if the temperature coefficient of the resistor R₂ can be decreased to about 0.3%/° C. using a thermistor, for example. However, implementing such a resistor on a silicon integrated circuit is impractical because of difficulties in use of special material, stability of the material temperature coefficient, resistance accuracy, and process complexity. Thus an alternative means is desired.

The logarithmic-compression analog-digital conversion circuit according to this example illustrated in FIG. 1 is configured so that the temperature variation can be reduced without specially setting the temperature coefficient of the resistor R₂. More specifically, this example comprises a logarithmic amplifier 30, a reference current source 24, reference voltage sources 26, 261, 262, and an A/D converter 60. The A/D converter 60 divides the reference voltage applied from the temperature-dependent reference voltage sources 261, 262 by a voltage dividing resistor 40, and inputs the divided comparison voltage and the logarithmically converted output voltage V_{OUT} to a comparator 42. Furthermore, the digital output from the comparator 42 is inputted to a logic circuit 44. The comparison voltage at the voltage dividing node of the voltage dividing resistor is suitably switched by a switch 45 under the control of the logic circuit and undergoes successive approximation and logic operation, providing a digital output voltage in which the error due to temperature variation is reduced.

Next, a more detailed description is given of the operation of using the temperature-dependent reference voltage sources to cancel the temperature variation of the logarithmically converted output voltage V_{OUT} of the logarithmic amplifier 30.

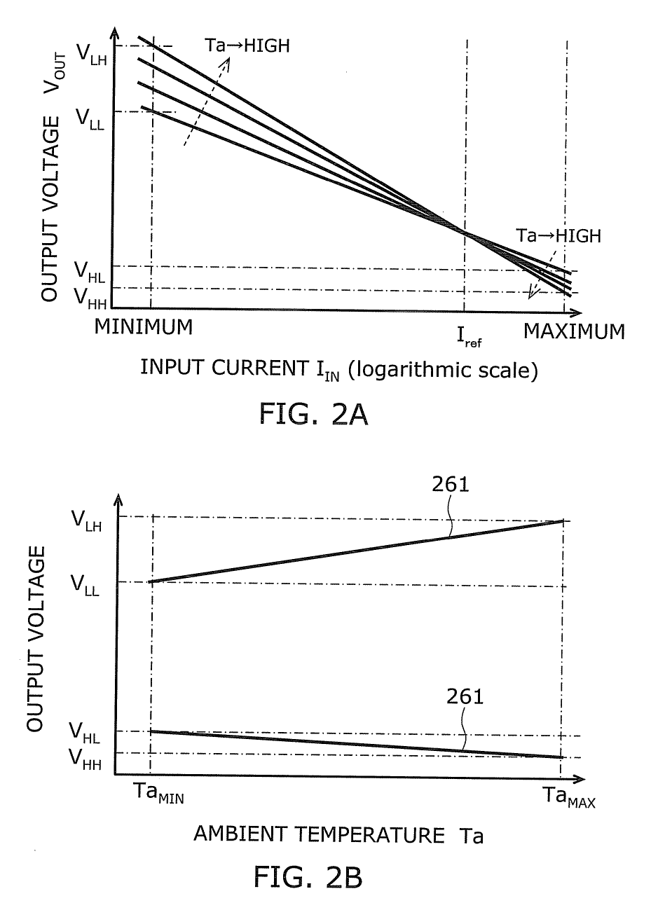

FIGS. 2A and 2B show graphs of a simulation result for illustrating the case where the reference current value I_{ref} configured in the logarithmic amplifier 30 is set within an intermediate range between the minimum and the maximum of the input current I_{IN} in the logarithmic amplifier 30.

Here, FIG. 2A is a graph showing the dependence of the output voltage V_{OUT} of the logarithmic amplifier 30 on the input current I_{IN} (logarithmic scale). The parameter is the ambient temperature Ta. FIG. 2B is a graph showing the ambient temperature dependence of the output voltage in the temperature-dependent reference voltage sources 261, 262. The reference current value I_{ref} is set to a prescribed value by the reference current source 24 connected to the logarithmic amplifier 30.

As can be seen from FIG. 2A, at the point where the input current I_{IN} coincides with the reference current value I_{ref}, the output voltage V_{OUT} from the logarithmic amplifier 30 scarcely varies despite the variation of ambient temperature Ta. In the input current range where the input current I_{IN} is lower than the reference current value I_{ref}, the output voltage V_{OUT} increases as the input current I_{IN} decreases. As the ambient temperature Ta increases, the voltage increase ratio increases. On the other hand, in the input current range where the input current I_{IN} is higher than the reference current value I_{ref}, the output voltage V_{OUT} decreases as the input current I_{IN} increases. As the ambient temperature Ta increases, the voltage decrease ratio increases.

More specifically, at the point where the input current I_{IN} is minimized, let V_{LL} denote the output voltage V_{OUT} from the logarithmic amplifier 30 for the ambient temperature Ta being the lowest, Ta_{MIN}, and V_{LH} denote V_{OUT} for the highest ambient temperature Ta_{MAX}. Then V_{LL}<V_{LH}. On the other hand, at the point where the input current I_{IN} is maximized, let V_{HL} denote V_{OUT} for the lowest ambient temperature Ta_{MIN}, and V_{HH} denote V_{OUT} for the highest ambient temperature Ta_{MAX}. Then V_{HL}>V_{HH}. Thus, in the logarithmic amplifier of an integrated circuit devoid of means for reducing temperature variation in logarithmic conversion, temperature variation of output voltage increases as the current deviates from the reference current value I_{ref}.

In digital conversion of analog output voltage by an A/D converter 60 of the resistor division successive approximation type, a divided voltage is produced by a voltage dividing resistor 40 composed of R₁₁, R₁₂, . . . , R₁ⱼ, . . . , R_{1N} (1≦j≦N) between a high-voltage side reference voltage terminal 301 and a low-voltage side reference voltage terminal 302. The output voltage V_{OUT} of the logarithmic amplifier 30 and this divided voltage are inputted to the comparator 42 for successive approximation, and thereby the value of each bit of digital output is determined. As a precondition for logarithmic digital conversion, it is necessary to set the count value of digital output for the minimum and maximum signal current. In FIG. 2A, it is assumed to set count 0 for the minimum of input current I_{IN} and to set the maximum count for the maximum of input current I_{IN}.

In this case, to the reference voltage terminal 301 corresponding to the I_{IN} minimum, V_{LH} is applied for Ta_{MAX} and V_{LL} is applied for Ta_{MIN}. Then the voltage corresponding to the I_{IN} minimum or count 0 can be set higher at high temperature and lower at low temperature. On the other hand, to the reference voltage terminal 302 corresponding to the I_{IN} maximum, V_{HH} is applied for Ta_{MAX} and V_{HL} is applied for Ta_{MIN}. Then the voltage corresponding to the I_{IN} maximum or the maximum count can be set lower at high temperature and higher at low temperature.

FIG. 2B is a graph showing the ambient temperature dependence of the output voltage of the temperature-dependent reference voltage sources 261 and 262 for such voltage setting. The output voltage of the temperature-dependent reference voltage source 261 is set to increase with the increase of ambient temperature Ta. That is, it is preferably set so that V_{LL} is outputted at Ta_{MIN} and V_{LH} is outputted at Ta_{MAX}. On the other hand, the output voltage of the temperature-dependent reference voltage source 262 is set to decrease with the increase of ambient temperature Ta. That is, it is preferably set so that V_{HL} is outputted at Ta_{MIN} and V_{HH} is outputted at Ta_{MAX}. By using these temperature-dependent reference voltage sources 261 and 262, the output count from the A/D converter 60 can be set to an equal value for a particular input current I_{IN} despite ambient temperature variation.

Next, a first variation for the setting of the reference current value I_{ref} is described.

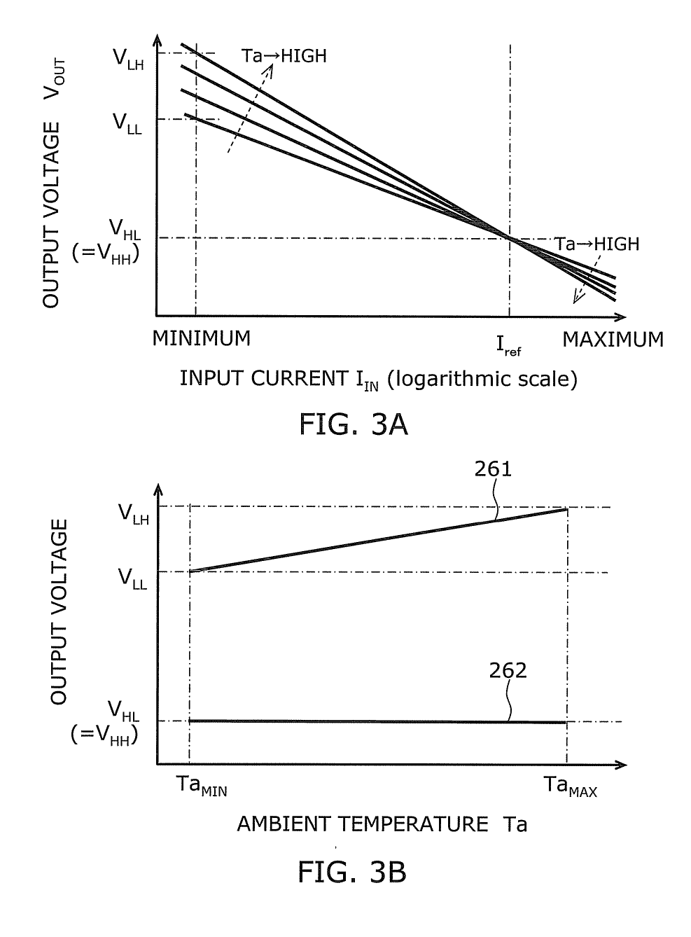

FIGS. 3A and 3B show graphs of a simulation result illustrating the case where the reference current value I_{ref} is matched with the I_{IN} maximum. More specifically, FIG. 3A is a graph showing the input current dependence of the output voltage V_{OUT} of the logarithmic amplifier 30, and FIG. 3B is a graph showing the ambient temperature dependence of the output voltage in the temperature-dependent reference voltage sources 261, 262.

In this case, as illustrated in FIG. 3A, temperature variation scarcely occurs at the I_{IN} maximum. On the other hand, in the input current range lower than the reference current value I_{ref}, the output voltage V_{OUT} increases as the ambient temperature Ta increases, and the output voltage V_{OUT}, which is V_{LL} at Ta_{MIN}, increases to V_{LH} at Ta_{MAX}.

FIG. 3B is a graph showing the ambient temperature dependence of the output voltage of the reference voltage sources for voltage setting in this case. The output voltage of the temperature-dependent reference voltage source 261 is set to increase with the increase of ambient temperature Ta. That is, it is preferably set so that V_{LL} is outputted at Ta_{MIN} and V_{LH} is outputted at Ta_{MAX}. On the other hand, the output voltage of the temperature-dependent reference voltage source 262 can be left constant (V_{HL}=V_{HH}) irrespective of ambient temperature variation. By using these reference voltage sources, the output count from the A/D converter 60 can be set to an equal value for a particular input current I_{IN} despite ambient temperature variation.

Next, a second variation for the setting of the reference current value I_{ref} is described.

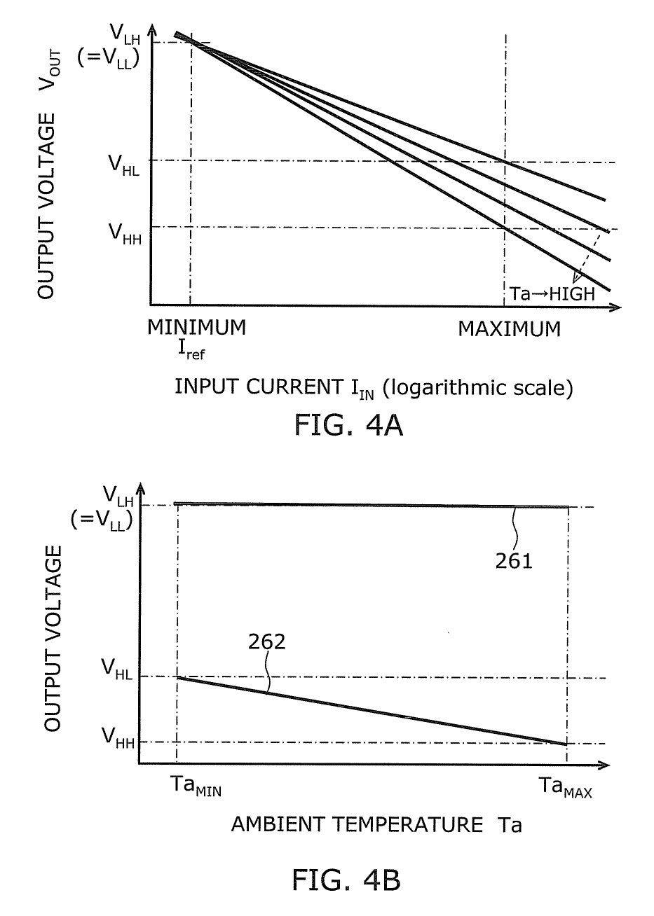

FIGS. 4A and 4B show graphs of a simulation result illustrating the case where the reference current value I_{ref} is matched with the I_{IN} minimum. More specifically, FIG. 4A shows the input current dependence of the output voltage V_{OUT} of the logarithmic amplifier 30, and FIG. 4B shows the ambient temperature dependence of the output voltage in the temperature-dependent reference voltage sources 261, 262.

In this case, as illustrated in FIG. 4A, temperature variation scarcely occurs at the I_{IN} minimum. On the other hand, in the input current range higher than the reference current value I_{ref}, the output voltage V_{OUT} decreases as the ambient temperature Ta increases, and the output voltage V_{OUT}, which is V_{HL} at Ta_{MIN}, decreases to V_{HH} at Ta_{MAX}.

FIG. 4B is a graph showing the ambient temperature dependence of the output voltage of the reference voltage sources for voltage setting in this case. The output voltage of the temperature-dependent reference voltage source 262 is set to decrease with the increase of ambient temperature Ta. That is, it is preferably set so that V_{HL} is outputted at Ta_{MIN} and V_{HH} is outputted at Ta_{MAX}. On the other hand, the output voltage of the temperature-dependent reference voltage source 261 can be left constant (V_{LH}=V_{LL}) irrespective of ambient temperature variation. By using these reference voltage sources, the output count from the A/D converter 60 can be set to an equal value for a particular input current I_{IN} despite ambient temperature variation. The method for setting the reference current value I_{ref} illustrated in FIGS. 3 and 4 allows one of the reference voltage sources to omit temperature dependence, and hence the configuration can be simplified.

In the A/D converter 60 shown in FIG. 1, the voltage dividing resistor 40 can be formed by using a standard integrated circuit process, and the cost can be reduced consequently. Furthermore, preferably, the A/D converter 60 and the logarithmic amplifier 30 are formed as integrated circuits. More preferably, they are formed on one chip.

The example described above can thus provide a logarithmic-compression analog-digital conversion circuit where a wide range of analog input current can be converted to a digital output voltage and the output count from the A/D converter 60 can be set to an equal value despite ambient temperature variation.

Next, a description is given of a semiconductor photosensor device with its digital output based on the logarithmic-compression analog-digital conversion circuit of this example.

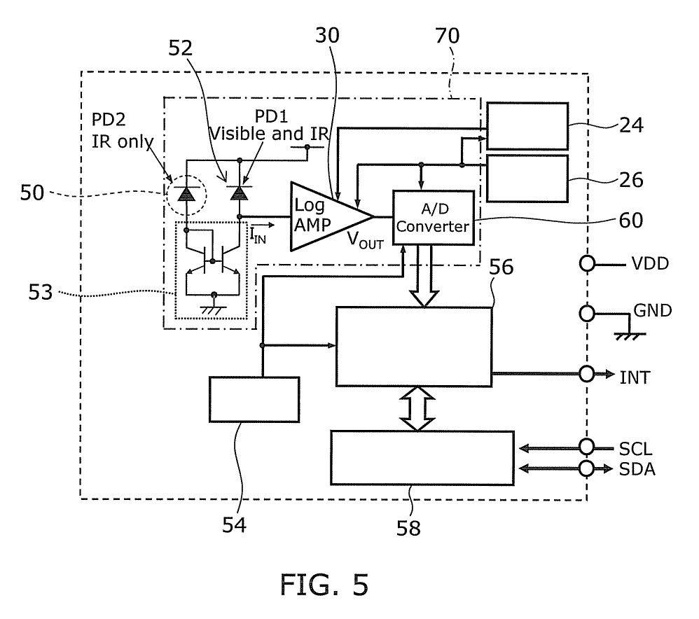

FIG. 5 is a block diagram of the semiconductor photosensor device. The first photodiode 52 detects visible and infrared light. The second photodiode 50 detects only infrared light because its light receiving element is covered with a visible light blocking filter. Currents from the first photodiode 52 and the second photodiode 50 are inputted to a current mirror 53 with the same multiplication factor. Thus the currents from the two photodiodes are subtracted from each other, and only the current I_{IN} generally corresponding to visible light is inputted to the logarithmic amplifier 30. That is, the input current I_{IN} has spectral characteristics close to visibility, which allows illuminance measurement with high accuracy. The two photodiodes 50 and 52, the current mirror circuit 53, amplifiers and other circuits are preferably configured as a silicon integrated circuit.

The output voltage V_{OUT} of the logarithmic amplifier 30 is inputted to the A/D converter 60. The reference current source 24 and the reference voltage source 26 are connected to the logarithmic amplifier 30. The reference voltage source 26 applies a temperature-dependent reference voltage to the A/D converter 60, thereby reducing the temperature variation of the logarithmic conversion coefficient. The digital output from the logarithmic-compression analog-digital conversion circuit with improved temperature characteristics is inputted to an adder 56 for averaging. A clock signal from a clock generator 54 is inputted to the A/D converter 60 and the adder 56. Digital signals are exchanged between the adder 56 and a 12C interface 58. It is more preferable that the first photodiode 52, the second photodiode 50, the current mirror circuit 53, the logarithmic amplifier 30, and the A/D converter 60 are put on one chip to form an integrated circuit 70.

In the digital output semiconductor photosensor device thus configured, currents over a wide dynamic range corresponding to incident light from low illuminance of several lux to high illuminance of several ten thousand lux can be converted to logarithmically compressed digital output voltages. Furthermore, the impact of temperature variation in logarithmic compression can be reduced by using a temperature-dependent reference voltage source.

Consequently, an illuminance sensor with a dynamic range of five or more orders of magnitude can be realized. That is, in low illuminance range, power consumption can be reduced by switching on/off the keypad LED. In high illuminance range, high-definition image display can be achieved by backlight brightness adjustment for a full-color liquid crystal display.

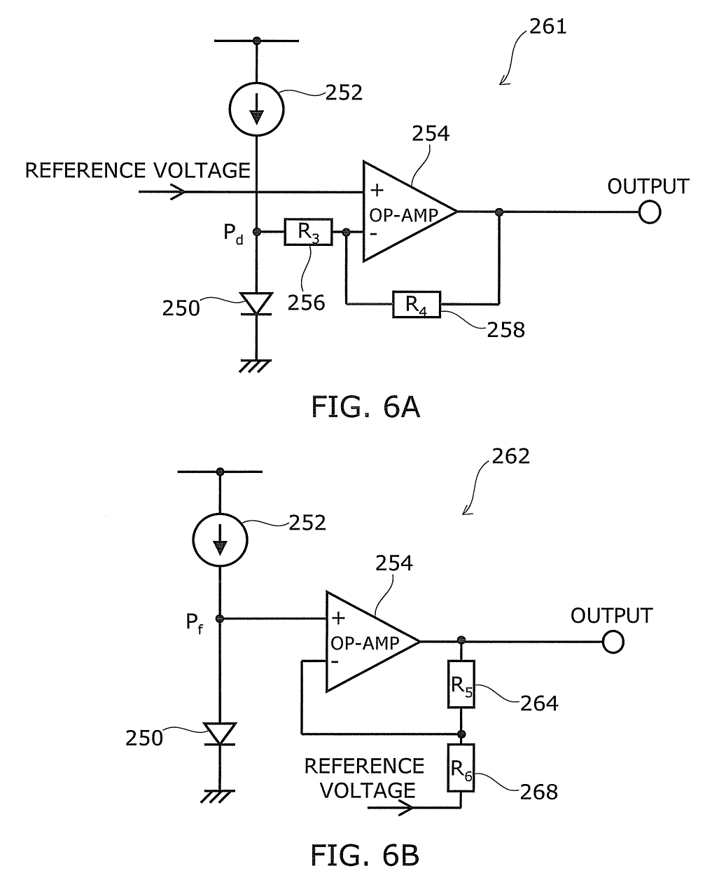

FIGS. 6A and 6B are circuits of the temperature-dependent reference voltage source. FIG. 6A is the temperature-dependent reference voltage source with a positive temperature coefficient. The positive temperature coefficient means that the output voltage increases with the increase of ambient temperature Ta. A diode 250 is provided between a current source 252 and a ground, and a point Pd connecting the current source 252 with the diode 250 is connected through a resistor 256 to an inverting input terminal (a negative input terminal) of an operational amplifier 254. The temperature-dependent reference voltage source 261 with the positive temperature coefficient can be achieved because a forward voltage of the diode 250 has a negative temperature coefficient and the operational amplifier 254 operates as an inverting amplifier.

On the other hand, FIG. 6B is the temperature-dependent reference voltage source with a negative temperature coefficient. The negative temperature coefficient means that the output voltage decreases with the increase of ambient temperature Ta. A point Pf connecting the current source 252 with the diode 250 is connected to a non-inverting input terminal (a positive input terminal) of the operational amplifier 254. The temperature-dependent voltage source 262 with the negative temperature coefficient can be achieved because the operational amplifier 254 operates as a non-inverting amplifier.

Furthermore, if a resistance ratio of the resistor 256 to a resistor 258 and a resistor ratio of a resistor 264 to a resistor 268 are varied, the output voltage dependence on temperature is adjusted using the negative temperature coefficient of the diode 250, approximately 2 mV/° C.

The voltage sources 26, 261, 262 and the reference current source 24 may not be included in the logarithmic-compression analog-digital converter circuit and the semiconductor photosensor device. However, if the temperature-dependent voltage sources 261 and 262, the logarithmic amplifier 30 and the A/D converter 60 are integrated on one chip, the temperature difference between the p-n junction of the logarithmic amplifier 30 and the p-n junction of the temperature-dependent voltage sources 261, 262 can be reduced, and hence it becomes easy to improve the temperature characteristics.

Furthermore, if R11, R12, . . . , Rij, . . . , RiN (1≦j≦N) composing the voltage dividing resistor 40 are set to approximately a same resistance value, the circuit of the A/D converter 60 can be simplified and it becomes easy to obtain higher comparing accuracy.

The embodiment of the invention has been described with reference to examples. However, the invention is not limited to these examples. For instance, the components of the logarithmic-compression analog-digital conversion circuit and the semiconductor photosensor device such as the operational amplifier, logarithmic amplifier, reference current source, reference voltage source, voltage dividing resistor, comparator, logic circuit, A/D converter, photodiode, and adder can be variously modified by those skilled in the art, and such modifications are also encompassed within the scope of the invention as long as they do not depart from the spirit of the invention.

1. A logarithmic-compression analog-digital conversion circuit, comprising:
a logarithmic amplifier configured to logarithmically convert an input current to a voltage using forward characteristics of a p-n junction, and configured to output the voltage; and
a converter configured to output a digital signal based on the output voltage of the logarithmic amplifier while reducing temperature dependence of the logarithmic amplifier by successively comparing the output voltage with a voltage generated from a reference voltage source which has a temperature dependence.

2. The logarithmic-compression analog-digital conversion circuit of claim 1, wherein a minimum count value of digital output is set for a minimum of the input current, and a maximum count value of digital output is set for a maximum of the input current.

3. The logarithmic-compression analog-digital conversion circuit of claim 1, wherein the converter includes a comparator which compares the output voltage of the logarithmic amplifier with the voltage generated from the reference voltage source, a logic circuit which outputs the digital signal based on an output from the comparator, and a voltage dividing resistor which generates a comparison voltage.

4. The logarithmic-compression analog-digital conversion circuit of claim 3, wherein the voltage dividing resistor includes a plurality of resistor elements which have a same resistance value.

5. The logarithmic-compression analog-digital conversion circuit of claim 3, wherein the voltage dividing resistor has an upper limit voltage having a positive temperature coefficient and supplied from the reference voltage source, and a lower limit voltage having a negative temperature coefficient and supplied from the reference voltage source, and a reference current is set to the logarithmic amplifier, the reference current being between minimum and maximum of the input current.

6. The logarithmic-compression analog-digital conversion circuit of claim 3, wherein the voltage dividing resistor has an upper limit voltage having a positive temperature coefficient and supplied from the reference voltage source, and a reference current is set to the logarithmic amplifier, the reference current being maximum of the input current.

7. The logarithmic-compression analog-digital conversion circuit of claim 3, wherein the voltage dividing resistor has a lower limit voltage having a negative temperature coefficient and supplied from the reference voltage source, and a reference current is set to the logarithmic amplifier, the reference current being minimum of the input current.

8. A logarithmic-compression analog-digital conversion circuit, comprising:
a means for converting an input current to an logarithmically compressed voltage using forward characteristics of a p-n junction,
a means for generating a reference voltage which has a temperature dependence, and
a means for outputting a digital signal while reducing temperature dependence of the logarithmically compressed voltage by successively comparing the logarithmically compressed voltage with the reference voltage.

9. The logarithmic-compression analog-digital conversion circuit of claim 8, wherein the reference voltage generating means has at least either a positive temperature coefficient or a negative temperature coefficient.

10. The logarithmic-compression analog-digital conversion circuit of claim 9, wherein the positive temperature coefficient is obtained by an operational amplifier, the operational amplifier operating as an inverting amplifier of which an inverting input terminal is connected through a resistor to a forward-biased p-n junction.

11. The logarithmic-compression analog-digital conversion circuit of claim 9, wherein the negative temperature coefficient is obtained by a operational amplifier, the operational amplifier operating as an non-inverting amplifier of which a non-inverting input terminal is connected to a forward-biased p-n junction.

12. A semiconductor photosensor device, comprising:
a photoelectric conversion element;
a logarithmic amplifier configured to logarithmically convert an input current to a voltage using forward characteristics of a p-n junction, and configured to output the voltage; and
a converter configured to output a digital signal based on the output voltage of the logarithmic amplifier while reducing temperature dependence of the logarithmic amplifier by successively comparing the output voltage with a voltage generated from a reference voltage source which has a temperature dependence.

13. The semiconductor photosensor device of claim 12, wherein a minimum count value of digital output is set for a minimum of the input current, and a maximum count value of digital output is set for a maximum of the input current.

14. The semiconductor photosensor device of claim 12, wherein the converter includes a comparator which compares the output voltage of the logarithmic amplifier with the voltage generated from the reference voltage source, a logic circuit which outputs the digital signal based on an output from the comparator, and a voltage dividing resistor which generates a comparison voltage.

15. The semiconductor photosensor device of claim 14, wherein the voltage dividing resistor is composed of a plurality of resistor elements which have a same resistance value.

16. The semiconductor photosensor device of claim 14, wherein the voltage dividing resistor has an upper limit voltage having a positive temperature coefficient and supplied from the reference voltage source, and a lower limit voltage having a negative temperature coefficient and supplied from the reference voltage source, and a reference current is set to the logarithmic amplifier, the reference current being between minimum and maximum of the input current.

17. The semiconductor photosensor device of claim 14, wherein the voltage dividing resistor has an upper limit voltage having a positive temperature coefficient supplied from the reference voltage, and a reference current is set to the logarithmic amplifier, the reference current being maximum of the input current.

18. The semiconductor photosensor device of claim 14, wherein the voltage dividing resistor has a lower limit voltage having a negative temperature coefficient and supplied from the reference voltage source, and a reference current is set to the logarithmic amplifier, the reference current being minimum of the input current.

19. The semiconductor photosensor device of claim 12, wherein the photoelectric conversion element includes a first photodiode and a second photodiode, the first photodiode detecting visible and infrared light, the second photodiode covered with a visible light blocking filter detecting only infrared light , and the input current being given by subtracting a current of the second photodiode from a current of the first photodiode.

20. The semiconductor photosensor device of claim 12, wherein the photoelectric conversion element, the logarithmic amplifier, and the converter are integrated on one chip.
